(19) United States
(12) Patent Application Publication
(10) Pub. No.: US 2025/0380552 A1
(43) Pub. Date: Dec. 11, 2025

(54) MICRO LIGHT-EMITTING DEVICE PACKAGE

(71) Applicant: LC SQUARE CO., LTD., Hwaseong-si, Gyeonggi-do (KR)

(72) Inventors: Je Hyuk CHOI, Yongin-si, Gyeonggi-do (KR); Jun Yeong SONG, Osan-si, Gyeonggi-do (KR); Yun Gwon WANG, Ansan-si, Gyeonggi-do (KR); Yong In JI, Pyeongtaek-si, Gyeonggi-do (KR); Sung Ki LEE, Anyang-si, Gyeonggi-do (KR)

(21) Appl. No.: 18/878,009

(22) PCT Filed: Jun. 30, 2023
(86) PCT No.: PCT/KR2023/009247

§ 371 Date: Dec. 21, 2024

(30) Foreign Application Priority Data
Jun. 30, 2022 (KR) 10-2022-0080726
Jun. 30, 2023 (KR) 10-2023-0084803

(51) Int. Cl. H10H 29/80

(52) U.S. Cl. CPC H10H 29/8321

(57) ABSTRACT

Provided is a micro light-emitting device package including a package frame including a first main surface and a second main surface extending parallel to each other, a red micro light-emitting device, a green micro light-emitting device, and a blue micro light-emitting device provided on the package frame, a common electrode pad extending from the first main surface to the second main surface of the package frame, individual electrode pads each extending from at least a portion of a lower part of each of the red micro light-emitting device, the green micro light-emitting device, and the blue micro light-emitting device through the package frame, at least one insulating layer extending along a side surface of each of the red micro light-emitting device, the green micro light-emitting device, and the blue micro light-emitting device, and a common electrode provided on top of the package frame and configured to electrically connect each of the red micro light-emitting device, the green micro light-emitting device, and the blue micro light-emitting device to the common electrode pad.

### TECHNICAL FIELD

The present invention relates to a micro light-emitting device package, and more particularly, to a micro light-emitting device package that is more compact while having significantly improved productivity in a transfer process.

### BACKGROUND ART

With the rapid advancement of electrical and electronic technologies, there may be a need to integrate various individual devices with different technical characteristics to meet the demands of a new era and diverse consumer requirements.

Accordingly, it is crucial to have a transfer method that enables individual devices (or individual components), which are manufactured based on different technologies on a source substrate, to be mass-transferred and integrated onto a wiring substrate (or a display substrate), i.e., a target substrate (or a destination substrate), without causing damage.

### DISCLOSURE

### Technical Problem

The present invention is directed to providing a micro light-emitting device package that is more compact while having significantly improved productivity in a transfer process.

### Technical Solution

In order to achieve the above technical object, the present invention provides a micro light-emitting device package including a package frame including a first main surface and a second main surface extending parallel to each other, a red micro light-emitting device, a green micro light-emitting device, and a blue micro light-emitting device provided on the package frame, a common electrode pad extending from the first main surface to the second main surface of the package frame, individual electrode pads each extending from at least a portion of a lower part of each of the red micro light-emitting device, the green micro light-emitting device, and the blue micro light-emitting device through the package frame, at least one insulating layer extending along a side surface of each of the red micro light-emitting device, the green micro light-emitting device, and the blue micro light-emitting device, and a common electrode provided on top of the package frame and configured to electrically connect each of the red micro light-emitting device, the green micro light-emitting device, and the blue micro light-emitting device to the common electrode pad.

In some embodiments, each of the red micro light-emitting device, the green micro light-emitting device, and the blue micro light-emitting device may include a p-type semiconductor layer, an active layer, and an n-type semiconductor layer, each p-type semiconductor layer is electrically connected to the common electrode, and each n-type semiconductor layer is connected to each individual electrode pad.

In some embodiments, side surfaces of the active layer and the n-type semiconductor layer may be vertically aligned.

In some embodiments, the common electrode may be a transparent electrode and may extend to cover each of the red micro light-emitting device, the green micro light-emitting device, and the blue micro light-emitting device.

In some embodiments, the common electrode may be a metal electrode and may at least partially expose a surface of each of the red micro light-emitting device, the green micro light-emitting device, and the blue micro light-emitting device.

In some embodiments, the n-type semiconductor layer may be positioned between the first main surface and the second main surface of the package frame.

In some embodiments, a height of each of the individual electrode pads in a thickness direction of the package frame may be less than a height of the common electrode pad.

In some embodiments, the n-type semiconductor layer may be directly connected to the individual electrode pad.

In some embodiments, each of the individual electrode pads may be in contact with only a lower surface of the n-type semiconductor layer when in contact with the n-type semiconductor layer.

According to another aspect of the present invention, there is provided a micro light-emitting device package including a micro light-emitting device including a first conductive semiconductor layer, an active layer, and a second conductive semiconductor layer sequentially stacked in a first direction, an insulating layer that covers a side surface of the micro light-emitting device, a first electrode positioned on a lower surface of the first conductive semiconductor layer in the first direction, a common electrode positioned on an upper surface of the second conductive semiconductor layer in the first direction, a second electrode positioned laterally to the first electrode in a second direction that is perpendicular to the first direction, and electrically connected to the common electrode, and a package substrate accommodating the first electrode and the second electrode, and separating the first electrode from the second electrode, wherein a maximum dimension of the micro light-emitting device in the second direction is about 5 μm to about 200 μm.

In some embodiments, the first electrode may extend parallel to the first direction from a lower surface of the first conductive semiconductor layer so as to extend away from the micro light-emitting device.

In some embodiments, the package frame may include a first main surface and a second main surface that extend parallel to each other, and the first electrode may extend from the first main surface to the second main surface of the package frame.

In some embodiments, the transparent electrode may extend to an upper surface of the second electrode. In some embodiments, the first conductive semiconductor layer may be a p-type semiconductor layer, and the second conductive semiconductor layer may be an n-type semiconductor layer.

In some embodiments, the common electrode may be a transparent electrode, and the common electrode may extend along a main surface of the package substrate and may be configured to cover the micro light-emitting device.

In some embodiments, the common electrode may be a metal electrode, and the common electrode may extend along a main surface of the package substrate and may be configured to at least partially expose the micro light-emitting device.

### Advantageous Effects

In a micro light-emitting device package of the present invention, three micro light-emitting devices corresponding to one pixel can be mounted on one package frame, thereby greatly improving productivity in subsequent transfer processes. Further, since three light-emitting devices are mounted at chip scale, a more compact mounting structure can be achieved.

### BRIEF DESCRIPTION OF THE DRAWINGS

FIG. 1 is a perspective view schematically illustrating a micro light-emitting device package according to one embodiment of the present invention.

FIG. 2 is a schematic cross-sectional view of the micro light-emitting device package according to one embodiment of the present invention, taken along line I-I′ of FIG. 1.

FIG. 3 is a schematic cross-sectional view of a micro light-emitting device package according to another embodiment of the present invention, taken along line I-I′ of FIG. 1.

FIGS. 4A to 4F are side cross-sectional views conceptually illustrating a method of manufacturing the micro light-emitting device package according to one embodiment of the present invention.

### DETAILED DESCRIPTION OF THE PREFERRED EMBODIMENTS

Hereinafter, exemplary embodiments of the present inventive concept will be described in detail with reference to the accompanying drawings. However, the embodiments of the present inventive concept can be modified into many different forms, and the scope of the present inventive concept should not be construed as being limited to the embodiments described below. It is preferred that the embodiments of the present inventive concept are interpreted as being provided to offer a more complete explanation of the present inventive concept to those of ordinary skill in the art. The same reference numerals refer to the same elements throughout the specification. Furthermore, various elements and areas in the drawings are schematically illustrated. Therefore, the present inventive concept is not limited by the relative sizes or intervals illustrated in the accompanying drawings.

The terms such as first, second, and the like can be used to describe various components, but these components are not limited by these terms. The terms are used solely for the purpose of distinguishing one component from another. For example, a first component may be named a second component without departing from the scope of the claims of the present inventive concept, and conversely, the second component may also be named the first component.

The terms used in the present application are merely used to describe specific embodiments and are not intended to limit the present inventive concept. Singular expressions include plural expressions unless the context clearly indicates otherwise. In the present application, it should be understood that terms such as “comprises” or “has” are intended to specify the presence of features, numbers, steps, operations, components, parts, or combinations thereof described in the specification, and do not preclude the possibility of the presence or addition of one or more other features, numbers, operations, components, parts, or combinations thereof.

Unless otherwise defined, all terms used herein, including technical and scientific terms, have the same meaning as commonly understood by those skilled in the art to which the present inventive concept pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

When a certain embodiment can be implemented differently, a specific process sequence may be performed differently from the described order. For example, two processes described in succession may be performed substantially at the same time or performed in an order opposite to the described order.

In the accompany drawings, variations in the shapes of the illustrations as a result, for example, of manufacturing techniques and/or tolerances, are to be expected. Thus, the embodiments of the present invention should not be construed as being limited to the particular illustrated shapes of regions, but are to include deviations in shapes that result from, for example, the manufacturing process. The term “and/or” used herein includes each and every combination of one or more of the stated components. In addition, as used herein, the term “substrate” may refer to the substrate itself, or a laminated structure including the substrate and a certain layer or film formed on a surface thereof. In addition, the term “surface of the substrate” may mean an exposed surface of the substrate itself, or an outer side surface such as a certain layer or film formed on the substrate.

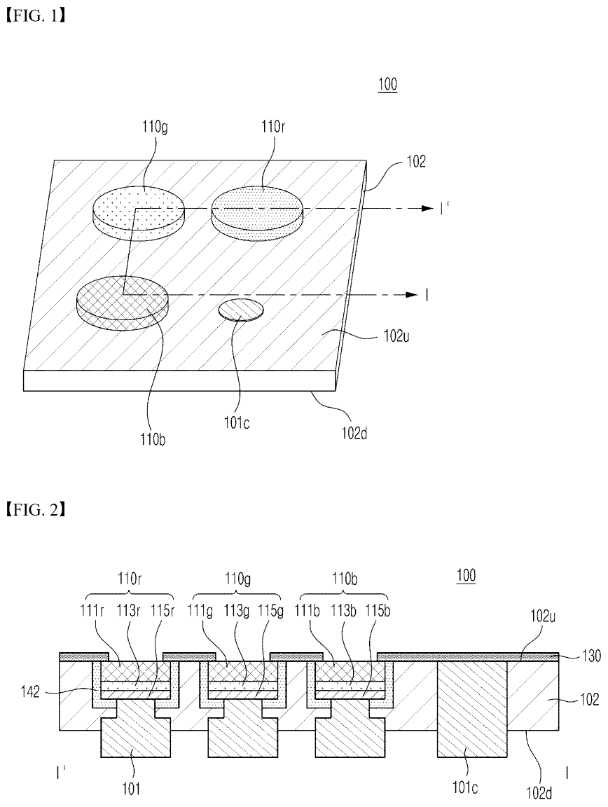

FIG. 1 is a perspective view schematically illustrating a micro light-emitting device package 100 according to one embodiment of the present invention.

Referring to FIG. 1, the micro light-emitting device package 100 may include a red micro light-emitting device 110r, a green micro light-emitting device 110g, and a blue micro light-emitting device 110b provided on one package frame 102.

The package frame 102 may include a first main surface 102u and a second main surface 102d that extend parallel to each other.

The package frame 102 is a single substrate and may be formed as, for example, a polymer, glass, or semiconductor substrate. In some embodiments, sub-pixels that form a single pixel in a display device may be provided on the package frame 102.

In some embodiments, one pixel may be provided on one package frame 102. In some embodiments, one pixel may include one red micro light-emitting device 110r, one green micro light-emitting device 110g, and one blue micro light-emitting device 110b. Each of the red, green, and blue micro light-emitting devices 110r, 110g, and 110b may act as a single sub-pixel.

In some embodiments, the red, green, and blue micro light-emitting devices 110r, 110g, and 110b may be arranged in a single row. In some other embodiments, the red, green, and blue micro light-emitting devices 110r, 110g, and 110b may be arranged in a grid form. In some other embodiments, the red, green, and blue micro light-emitting devices 110r, 110g, and 110b may be arranged in a triangular form. In some other embodiments, the red, green, and blue micro light-emitting devices 110r, 110g, and 110b may be arranged in a line.

Since three sub-pixels are mounted on one package frame 102, a display module can be manufactured more quickly compared to handling each micro light-emitting device that forms a sub-pixel individually for mounting on a display substrate.

FIG. 2 is a schematic cross-sectional view of the micro light-emitting device package 100 according to one embodiment of the present invention, taken along line I-I′ of FIG. 1.

Referring to FIG. 2, the micro light-emitting device package 100 includes a common electrode pad 101c extending from the first main surface 102u to the second main surface 102d of the package frame 102. The common electrode pad 101c may include any electrically conductive material, for example, aluminum (Al), copper (Cu), nickel (Ni), palladium (Pd), iridium (Ir), ruthenium (Ru), magnesium (Mg), platinum (Pt), zinc (Zn), gold (Au), silver (Ag), iron (Fe), cobalt (Co), or an alloy containing one or more of these materials.

The micro light-emitting device package 100 includes individual electrode pads 101 each extending from a portion of a lower part of each of the light-emitting devices 110r, 110g, and 110b through the package frame 102.

In some embodiments, the individual electrode pads 101 may extend at least from the first main surface 102u to the second main surface 102d of the package frame 102. In some embodiments, the individual electrode pads 101 may respectively extend from the lower parts of the red, green, and blue micro light-emitting devices 110r, 110g, and 110b to at least the second main surface 102d.

The individual electrode pads 101 may include any electrically conductive material, for example, aluminum (Al), copper (Cu), nickel (Ni), palladium (Pd), iridium (Ir), ruthenium (Ru), magnesium (Mg), platinum (Pt), zinc (Zn), gold (Au), silver (Ag), iron (Fe), cobalt (Co), or an alloy containing one or more of these materials.

The red, green, and blue micro light-emitting devices 110r, 110g, and 110b may respectively include first conductive semiconductor layers 111r, 111g, and 111b, active layers 113r, 113g, and 113b, and second conductive semiconductor layers 115r, 115g, and 115b.

In some embodiments, the first conductive semiconductor layers 111r, 111g, and 111b may be p-type semiconductor layers, and the second conductive semiconductor layers 115r, 115g, and 115b may be n-type semiconductor layers. In some other embodiments, the first conductive semiconductor layers 111r, 111g, and 111b may be n-type semiconductor layers, and the second conductive semiconductor layers 115r, 115g, and 115b may be p-type semiconductor layers. Here, the case in which the first conductive semiconductor layers 111r, 111g, and 111b are p-type semiconductor layers and the second conductive semiconductor layers 115r, 115g, and 115b are n-type semiconductor layers will be mainly described.

Each of the first conductive semiconductor layers 111r, 111g, and 111b and the second conductive semiconductor layers 115r, 115g, and 115b may be made of a material with the composition of a Group III nitride semiconductor, such as AlₓIn_{γ}Ga_{(1-x-γ)}N (0≤x≤1, 0≤y≤1, and 0≤x+y≤1). Of course, the present invention is not limited thereto, and materials such as AlGaInP-based semiconductors or AlGaAs-based semiconductors may also be used.

Meanwhile, the first conductive semiconductor layers 111r, 111g, and 111b and the second conductive semiconductor layers 115r, 115g, and 115b may each be formed as a single-layer structure, but, alternatively, may be formed as a multi-layer structure with different compositions or thicknesses as needed. For example, each of the first conductive semiconductor layers 111r, 111g, and 111b and the second conductive semiconductor layers 115r, 115g, and 115b may include a carrier injection layer that can improve the injection efficiency of electrons and holes, and may also have various types of superlattice structures.

The first conductive semiconductor layers 111r, 111g, and 111b may each further include a current spreading layer (not shown) in a portion adjacent to the active layers 113r, 113g, and 113b. The current spreading layer may have a structure in which a plurality of InₓAl_{γ}Ga_{(1-x-γ)}N layers with different compositions or different impurity contents are repeatedly stacked, or may include a partially formed insulating material layer.

The second conductive semiconductor layers 115r, 115g, and 115b may each further include an electron blocking layer (not shown) in a portion adjacent to the active layers 113r, 113g, and 113b. The electron blocking layer may have a structure in which a plurality of layers of InₓAl_{γ}Ga_{(1-x-γ)}N with different compositions are stacked, or alternatively, may include one or more layers composed of AlyGa_{(1-γ)}N. The electron blocking layer has a larger bandgap than the active layers 113r, 113g, and 113b, thereby preventing electrons from going into the second conductive semiconductor layers 115r, 115g, and 115b.

In addition, the active layers 113r, 113g, and 113b may each have a multi-quantum well (MQW) structure in which quantum well layers and quantum barrier layers are alternately stacked. For example, in the case of nitride semiconductors, a GaN/InGaN structure may be used, but, a single quantum well (SQW) structure may also be employed.

The active layers 113r, 113g, and 113b and the second conductive semiconductor layers 115r, 115g, and 115b may have their side surfaces aligned. In some embodiments, the first conductive semiconductor layers 111r, 111g, and 111b, the active layers 113r, 113g, and 113b, and the second conductive semiconductor layers 115r, 115g, and 115b may have their side surfaces aligned with each other.

In some embodiments, the first conductive semiconductor layers 111r, 111g, and 111b may be electrically connected to the common electrode pad 101c. Specifically, the first conductive semiconductor layers 111r, 111g, and 111b of the red, green, and blue micro light-emitting devices 110r, 110g, and 110b may each be connected to a common electrode 130, and the common electrode 130 may be connected to the common electrode pad 101c.

In some embodiments, the common electrode 130 may extend laterally across an upper part of the micro light-emitting device package 100. That is, the common electrode 130 may extend along an upper surface of the package frame 102, from an upper part of one side end of the package frame 102 to an upper part of the other side end of the package frame 102.

In some embodiments, the common electrode 130 may be a transparent electrode. The transparent electrode may include a material that is optically transparent to visible light, such as, for example, indium-tin oxide (ITO), indium-zinc oxide (IZO), or the like. When the common electrode 130 is a transparent electrode, the common electrode 130 may extend to cover the red, green, and blue micro light-emitting devices 110r, 110g, and 110b.

In some embodiments, the common electrode 130 may include an extremely thin metal, such as copper, gold, silver, iron, cobalt, nickel, or an alloy thereof. When the common electrode 130 is composed of a metal or a metal alloy, the common electrode 130 may become optically nearly transparent when a thickness thereof is sufficiently small, thereby achieving a level of transparency comparable to that of a transparent electrode such as ITO or IZO. However, when the common electrode 130 is optically opaque or not sufficiently transparent, the common electrode 130 may at least partially expose each of the red, green, and blue micro light-emitting devices 110r, 110g, and 110b so that light can be emitted from the red, green, and blue micro light-emitting devices 110r, 110g, and 110b.

A first insulating layer 142, which is a passivation layer, may be provided on the side surfaces of each of the micro light-emitting devices 110r, 110g, and 110b. The first insulating layer 142 may extend along the side surfaces of the active layers 113r, 113g, and 113b and the second conductive semiconductor layers 115r, 115g, and 115b. In some embodiments, the first insulating layer 142 may extend along the side surfaces of the first conductive semiconductor layers 111r, 111g, and 111b, the active layers 113r, 113g, and 113b, and the second conductive semiconductor layers 115r, 115g, and 115b. In some embodiments, the first insulating layer 142 may extend along the side surfaces of the first conductive semiconductor layers 111r, 111g, and 111b, the active layers 113r, 113g, and 113b, and the second conductive semiconductor layers 115r, 115g, and 115b in a substantially conformal manner.

Here, the fact that first insulating layer 142 is “substantially conformal” means that a difference between the maximum thickness and the minimum thickness while the first insulating layer 142 extends is within 50% of the maximum thickness.

The first insulating layer 142 may be made of an electrically insulating material. In some embodiments, the first insulating layer 142 may include inorganic materials such as silicon oxide, silicon nitride, silicon oxynitride, and the like. However, the present invention is not limited thereto.

In some embodiments, the first insulating layer 142 may extend along the side surfaces of each of the active layers 113r, 113g, and 113b and the first conductive semiconductor layers 111r, 111g, and 111b, and then extend horizontally for a predetermined length along a lower surface of each of the second conductive semiconductor layers 115r, 115g, and 115b.

In some embodiments, an ohmic contact layer may be further provided on an upper surface of each of the first conductive semiconductor layers 111r, 111g, and 111b. The ohmic contact layer may include a material that is optically transparent to visible light, such as indium-tin oxide (ITO), indium-zinc oxide (IZO), or the like. In some embodiments, the ohmic contact layer may include the same material as the common electrode 130. In some embodiments, the ohmic contact layer may be formed of GaN, InGaN, ZnO, or a graphene layer. The ohmic contact layer may reduce an operating voltage of the device and improve device characteristics by relatively increasing an impurity concentration to lower ohmic contact resistance.

In some embodiments, the first insulating layer 142 may extend horizontally along the lower surface of each of the second conductive semiconductor layers 115r, 115g, and 115b up to a side surface of the individual electrode pad 101. In addition, on the upper surfaces of the first conductive semiconductor layers 111r, 111g, and 111b, the common electrode 130 may extend horizontally along upper parts of the ohmic contact layer and the first conductive semiconductor layers 111r, 111g, and 111b.

In some embodiments, the second conductive semiconductor layers 115 may be positioned between the first main surface 102u and the second main surface 102d. At this time, the lower surfaces of the second conductive semiconductor layers 115r, 115g, and 115b may be in direct contact with upper surfaces of the individual electrode pads 101, respectively. The individual electrode pads 101 may extend in a direction away from the light-emitting devices 110 from the lower surfaces of the second conductive semiconductor layers 115r, 115g, and 115b. In some embodiments, when the individual electrode pads 101 are in contact with the second conductive semiconductor layers 115r, 115g, and 115b, the individual electrode pads 101 may be in contact with only the lower surfaces of the second conductive semiconductor layers 115r, 115g, and 115b, respectively.

In some embodiments, the upper surfaces of the second conductive semiconductor layers 115r, 115g, and 115b may be entirely in contact with the active layers 113r, 113g, and 113b, respectively, and the side surfaces of the second conductive semiconductor layers 115r, 115g, and 115b may be entirely in contact with the first insulating layer 142.

FIG. 3 is a schematic cross-sectional view of a micro light-emitting device package 100a according to another embodiment of the present invention, taken along line I-I′ of FIG. 1.

The micro light-emitting device package 100a in FIG. 3 is the same as the micro light-emitting device package 100 in FIG. 2, except that a transparent electrode 130t is used as the common electrode. Accordingly, the configuration of the invention will be described focusing on this difference.

Referring to FIG. 3, the transparent electrode 130t, which is the common electrode, extends along the first main surface 102u of the package frame 102. The transparent electrode 130t may be in contact with the common electrode pad 101c. The transparent electrode 130t may extend continuously along the first main surface 102u to cover the upper surfaces of the micro light-emitting devices 110r, 110g, and 110b. The transparent electrode 130t is optically transparent, and thus, even when the transparent electrode 130t covers the upper surfaces of the micro light-emitting devices 110r, 110g, and 110b, the transparent electrode 130t does not prevent light generated from the micro light-emitting devices 110r, 110g, and 110b from being emitted to the outside.

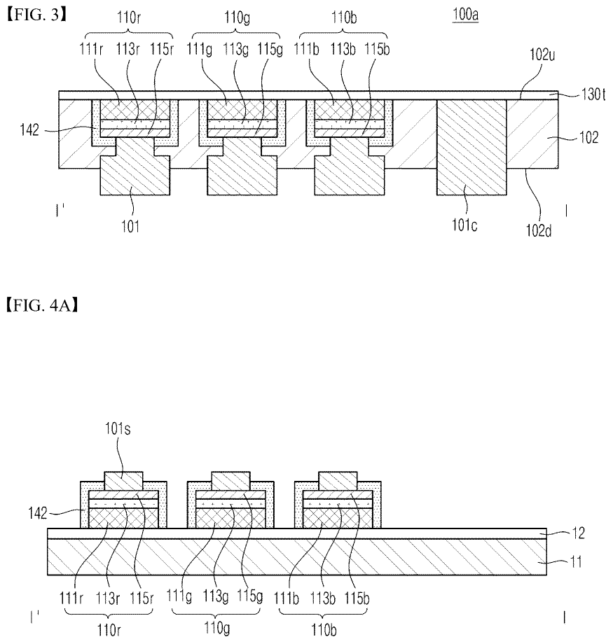

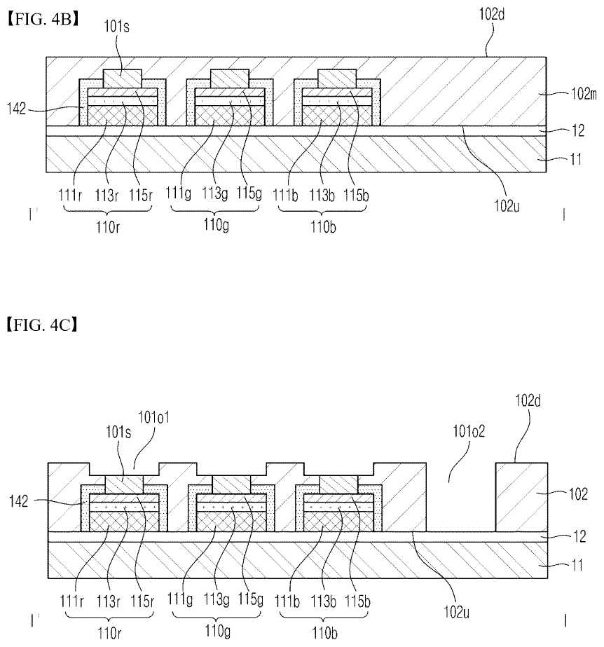

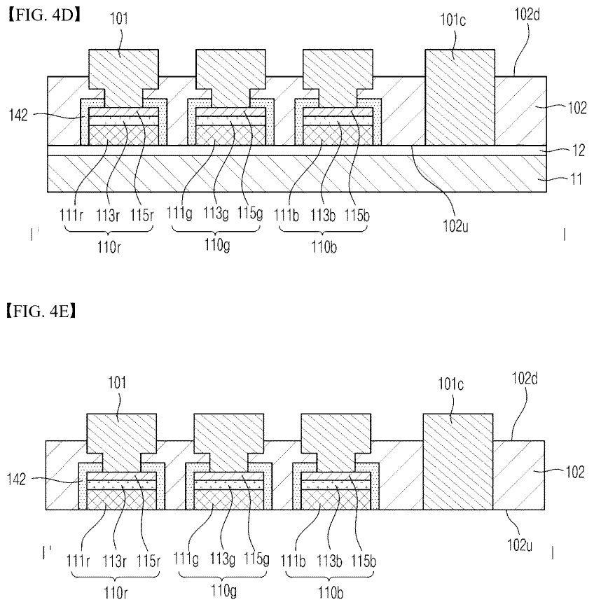

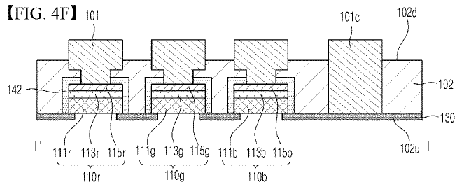

FIGS. 4A to 4F are side cross-sectional views conceptually illustrating a method of manufacturing the micro light-emitting device package 100 according to one embodiment of the present invention.

Referring to FIG. 4A, micro light-emitting devices 110r, 110g, and 110b may be placed on an interposer substrate 11.

The micro light-emitting devices 110r, 110g, and 110b may be fabricated on a different substrate and then transferred onto the interposer substrate 11 using a method, for example, laser transfer. The micro light-emitting devices 110r, 110g, and 110b may respectively include first conductive semiconductor layers 111r, 111g, and 111b, active layers 113r, 113g, and 113b, and second conductive semiconductor layers 115r, 115g, and 115b. In addition, a first insulating layer 142 may be formed on side surfaces of each of the micro light-emitting devices 110r, 110g, and 110b. The above configurations have been described with reference to FIG. 2, and thus, duplicated description will be omitted here.

An electrode source layer 101s may be formed on one side of each of the micro light-emitting devices 110r, 110g, and 110b. The electrode source layer 101s includes a conductive material, for example, a metal such as copper. In some embodiments, the electrode source layer 101s may act as a seed layer for subsequent electroplating. However, the present invention is not limited thereto.

The micro light-emitting devices 110r, 110g, and 110b may be attached to the interposer substrate 11 by an adhesive layer 12. The adhesive layer 12 may include any adhesive widely used in the art, such as an epoxy-based adhesive.

Referring to FIG. 4B, a package frame material layer 102m may be formed to surround the side and upper surfaces of each of the micro light-emitting devices 110r, 110g, and 110b. The package frame material layer 102m is an electrically insulating material and, for example, may include an electrically insulating polymer material. The package frame material layer 102m may include, for example, an epoxy molding compound (EMC).

The package frame material layer 102m may be formed by injection molding in a mold. However, the present invention is not limited thereto.

A contact surface of the package frame material layer 102m with the adhesive layer 12 may form a first main surface 102u, and a surface opposite thereto may form a second main surface 102d.

As shown in FIG. 4B, the package frame material layer 102m may be formed to surround the side and upper surfaces of each of the micro light-emitting devices 110r, 110g, and 110b, and to completely cover an upper surface of each electrode source layer 101s.

Referring to FIG. 4C, in order to form a space for forming electrode pads, a first opening 101o1 and a second opening 101o2 may be formed in the package frame material layer 102m.

The first opening 101o1 may be formed to expose the electrode source layer 101s of each of the micro light-emitting devices 110r, 110g, and 110b. A horizontal width of the first opening 101o1 may be determined in consideration of the resistance of each individual electrode pad to be manufactured later. In some embodiments, the horizontal width of the first opening 101o1 may be greater than a horizontal width of the electrode source layer 101s.

In some embodiments, the entire upper surface of the electrode source layer 101s may be exposed by the first opening 101o1.

The second opening 101o2 may be an opening for forming a common electrode pad and may be formed such that the adhesive layer 12 is exposed at a location at which the common electrode pad is to be formed. A horizontal width of the second opening 101o2 may be determined in consideration of the resistance of the common electrode pad to be manufactured later.

The first opening 101o1 and the second opening 101o2 may be formed in separate processes, or may be formed in a single process. The first opening 101o1 and the second opening 101o2 may be formed by placing a mask, which exposes locations at which the first opening 101o1 and the second opening 101o2 are to be formed, on the package frame material layer 102m, and selectively removing the exposed portions of the package frame material layer 102m. However, the present invention is not limited thereto, and the first opening 101o1 and the second opening 101o2 may be formed by any method known to a person of ordinary skill in the art.

Referring to FIG. 4D, an individual electrode pad 101 may be formed in the first opening 101o1, and a common electrode pad 101c may be formed in the second opening 101o2.

The individual electrode pad 101 and the common electrode pad 101c may be formed, for example, by plating. By forming a seed layer in each of the first opening 101o1 and the second opening 101o2 and applying power in a plating bath, the individual electrode pad 101 and the common electrode pad 101c may be formed. However, the present invention is not limited thereto, and a person of ordinary skill in the art will understand that other methods such as electroless plating, physical vapor deposition, and chemical vapor deposition may be used to form the individual electrode pads 101 and the common electrode pad 101c.

A height of the individual electrode pad 101 in a vertical direction may be less than a height of the common electrode pad 101c in the vertical direction. In some embodiments, an upper surface of the individual electrode pad 101 and an upper surface of the common electrode pad 101c may be positioned on substantially the same plane.

In some embodiments, the individual electrode pads 101 and the common electrode pad 101c may protrude from the second main surface 102d. In some other embodiments, the individual electrode pads 101 and the common electrode pad 101c may be positioned on substantially the same plane as the second main surface 102d.

Referring to FIG. 4E, the interposer substrate 11 and the adhesive layer 12 may be removed. The micro light-emitting devices 110r, 110g, and 110b may be exposed by the removal of the interposer substrate 11 and the adhesive layer 12.

The interposer substrate 11 and the adhesive layer 12 may be removed by any method known in the art, such as delamination, peeling, and the like and are not particularly limited to a specific method.

Referring to FIG. 4F, a common electrode 130 is formed on the first main surface 102u. The common electrode 130 may be an optically transparent electrode or an optically opaque electrode, for example, a metal electrode.

As described above, when the common electrode 130 is optically opaque or not sufficiently transparent, the common electrode 130 may be formed to at least partially expose each of the micro light-emitting devices 110r, 110g, and 110b. However, since the common electrode 130 must be electrically connected to the first conductive semiconductor layers 111r, 111g, and 111b of the micro light-emitting devices 110r, 110g, and 110b, the common electrode 130 may extend to partially come into contact with each of the first conductive semiconductor layers 111r, 111g, and 111b.

The common electrode 130 may virtually cover the entire first main surface 102u except for portions from which light of the micro light-emitting devices 110r, 110g, and 110b is emitted.

In some embodiments, the common electrode 130 may be an optically transparent electrode. In this case, the common electrode 130 may be formed to cover the micro light-emitting devices 110r, 110g, and 110b. Specifically, the common electrode 130 may be formed to cover the first conductive semiconductor layers 111r, 111g, and 111b of the micro light-emitting devices 110r, 110g, and 110b.

Since the common electrode 130 is optically transparent, light may be emitted even when the first conductive semiconductor layers 111r, 111g, and 111b of the micro light-emitting devices 110r, 110g, and 110b are covered by the common electrode 130.

While the embodiments of the present invention have been described in detail above, those skilled in the art to which the present invention pertains will appreciate that various modifications and variations can be made to the present invention without departing from the spirit and scope of the invention as defined by the appended claims. Accordingly, future modifications of the embodiments of the present invention will not depart from the scope of the present invention.

1. A micro light-emitting device package comprising:
a package frame including a first main surface and a second main surface extending parallel to each other;
a red micro light-emitting device, a green micro light-emitting device, and a blue micro light-emitting device provided on the package frame;
a common electrode pad extending from the first main surface to the second main surface of the package frame;
individual electrode pads each extending from at least a portion of a lower part of each of the red micro light-emitting device, the green micro light-emitting device, and the blue micro light-emitting device through the package frame;
at least one insulating layer extending along a side surface of each of the red micro light-emitting device, the green micro light-emitting device, and the blue micro light-emitting device; and
a common electrode provided on top of the package frame and configured to electrically connect each of the red micro light-emitting device, the green micro light-emitting device, and the blue micro light-emitting device to the common electrode pad.

2. The micro light-emitting device package of claim 1, wherein each of the red micro light-emitting device, the green micro light-emitting device, and the blue micro light-emitting device includes a p-type semiconductor layer, an active layer, and an n-type semiconductor layer, each p-type semiconductor layer is electrically connected to the common electrode, and each n-type semiconductor layer is connected to each individual electrode pad.

3. The micro light-emitting device package of claim 2, wherein side surfaces of the active layer and the n-type semiconductor layer are vertically aligned.

4. The micro light-emitting device package of claim 2, wherein the common electrode is a transparent electrode and extends to cover each of the red micro light-emitting device, the green micro light-emitting device, and the blue micro light-emitting device.

5. The micro light-emitting device package of claim 2, wherein the common electrode is a metal electrode and at least partially exposes a surface of each of the red micro light-emitting device, the green micro light-emitting device, and the blue micro light-emitting device.

6. The micro light-emitting device package of claim 2, wherein the n-type semiconductor layer is positioned between the first main surface and the second main surface of the package frame.

7. The micro light-emitting device package of claim 6, wherein a height of each of the individual electrode pads in a thickness direction of the package frame is less than a height of the common electrode pad.

8. The micro light-emitting device package of claim 2, wherein the n-type semiconductor layer is directly connected to the individual electrode pad.

9. The micro light-emitting device package of claim 8, wherein each of the individual electrode pads is in contact with only a lower surface of the n-type semiconductor layer when in contact with the n-type semiconductor layer.

10. A micro light-emitting device package comprising:
a micro light-emitting device including a first conductive semiconductor layer, an active layer, and a second conductive semiconductor layer sequentially stacked in a first direction;
an insulating layer that covers a side surface of the micro light-emitting device;
a first electrode positioned on a lower surface of the first conductive semiconductor layer in the first direction;
a common electrode positioned on an upper surface of the second conductive semiconductor layer in the first direction;
a second electrode positioned laterally to the first electrode in a second direction that is perpendicular to the first direction, and electrically connected to the common electrode; and
a package substrate accommodating the first electrode and the second electrode, and separating the first electrode from the second electrode,
wherein a maximum dimension of the micro light-emitting device in the second direction is about 5 μm to about 200 μm.

11. The micro light-emitting device package of claim 10, wherein the first electrode extends parallel to the first direction from a lower surface of the first conductive semiconductor layer so as to extend away from the micro light-emitting device.

12. The micro light-emitting device package of claim 11, wherein the package frame includes a first main surface and a second main surface that extend parallel to each other, and the first electrode extends from the first main surface to the second main surface of the package frame.

13. The micro light-emitting device package of claim 10, wherein the common electrode extends to an upper surface of the second electrode.

14. The micro light-emitting device package of claim 10, wherein the first conductive semiconductor layer is a p-type semiconductor layer, and the second conductive semiconductor layer is an n-type semiconductor layer.

15. The micro light-emitting device package of claim 10, wherein the common electrode is a transparent electrode, and
the common electrode extends along a main surface of the package substrate and is configured to cover the micro light-emitting device.

16. The micro light-emitting device package of claim 10, wherein the common electrode is a metal electrode, and
the common electrode extends along a main surface of the package substrate and is configured to at least partially expose the micro light-emitting device.
